(19) United States
(12) Patent Application Publication
(10) Pub. No.: US 2024/0138238 A1
(43) Pub. Date: Apr. 25, 2024

(54) DISPLAY APPARATUS

(71) Applicant: LG Display Co., Ltd., Seoul (KR)

(72) Inventor: Yongsang KIM, Paju-si (KR)

(73) Assignee: LG Display Co., Ltd., Seoul (KR)

(21) Appl. No.: 18/381,501

(22) Filed: Oct. 17, 2023

(30) Foreign Application Priority Data
Oct. 18, 2022 (KR) 10-2022-0134626

(51) Int. Cl. H10K 59/80; B60K 37/02

(52) U.S. Cl. CPC H10K 59/874; B60K 37/02; H10K 59/8792; B60K 2370/1533; H10K 2102/311

(57) ABSTRACT

A display apparatus includes a support member, a display panel located above the support member, a fixing layer between the support member and the display panel, a cover member located above the display panel and including an active area and a non-active area adjacent the active area, and at least one light shielding layer disposed on a rear surface of the cover member and overlapping the non-active area. The support member includes a base part overlapping the display panel and at least one extension part extending from the base part and protruding from a side surface of the display panel. Further, the extension part covers the side surface of the display panel.

### CROSS-REFERENCE TO RELATED APPLICATION

The present application claims priority to Korean Patent Application No. 10-2022-0134626, filed Oct. 19, 2022 in the Republic of Korea, the entire contents of which are hereby expressly incorporated by reference into the present application.

### BACKGROUND

### Field

The present disclosure relates to a display apparatus configured to minimize permeation of moisture and oxygen.

### Discussion of the Related Art

A display apparatus used in a computer monitor, a television, a mobile electronic device, a home appliance, or a vehicle can include an organic light emitting display that automatically emits light or a liquid crystal display that requires a separate light source.

Recently, a flexible display apparatus, which is manufactured to display an image even when it is bent like paper, by forming display elements and wires on a flexible substrate made of a flexible material such as plastic, is attracting attention as a next-generation display apparatus.

### SUMMARY OF THE DISCLOSURE

According to one embodiment of the present disclosure, the present disclosure provides a display apparatus which can efficiently block penetration (or permeation) of moisture (H2O) and/or oxygen (O2).

According to another embodiment of the present disclosure, the present disclosure provides a display apparatus in which an organic light emitting element is used as a light source, and penetration (or permeation) of moisture (H2O) and/or oxygen (O2) is efficiently blocked or minimized to prevent damage to the organic light emitting element.

According to still another embodiment of the present disclosure, the present disclosure is intended to propose a display apparatus in which a rear printed part of a cover member can be protected, and scratches can be prevented or minimized.

Objectives to be obtained according to the embodiments of the present disclosure are not limited to the objectives mentioned above, and other objectives not mentioned will be clearly understood by those skilled in the art from the description below.

In order to achieve the above objectives, according to one aspect of the present disclosure, there is provided a display apparatus including: a support member, a display panel located above the support member, a fixing layer between the support member and the display panel, a cover member located above the display panel and including an active area and a non-active area around the active area, and at least one light shielding layer disposed on a rear surface of the cover member and overlapping the non-active area. The support member includes a base part overlapping the display panel and at least one extension part extending from the base part and protruding from a side surface of the display panel, wherein the extension part covers the side surface of the display panel.

The display apparatus according to the embodiments of the present disclosure includes the display panel having an active area and a non-active area; the cover member disposed above the display panel; the support member disposed under the display panel; and the fixing layer configured to attach the support member. An area of the support member can be larger than an area of the display panel.

Other embodiments specifics are included in the detailed description and drawings.

According to an embodiment of the present disclosure, moisture (H2O) and oxygen (O2) are blocked from penetrating into the display apparatus, so that the display apparatus can be efficiently protected. In addition, damage to the display apparatus due to external force can be prevented or minimized.

In the display apparatus according to the embodiments of the present disclosure, a light emitting part is not damaged even when exposed to an external environment, so the display apparatus can have excellent presentation reliability. Accordingly, the display apparatus according to the embodiments of the present disclosure can be usefully used not only for indoor use, but also for outdoor use such as for a vehicle.

In addition, in the display apparatus according to one embodiment of the present disclosure, a rear printed part of the cover member can be protected, and scratching thereof can be prevented.

Effects of the present disclosure are not limited to the effects mentioned above, and other effects not mentioned will be clearly understood by those skilled in the art from the following description.

### BRIEF DESCRIPTION OF THE DRAWINGS

The present disclosure will become more fully understood from the detailed description given hereinbelow and the accompanying drawings which are given by way of illustration only, and thus are not limitative of the present disclosure.

FIG. 1 is an exploded perspective view illustrating a display apparatus according to one embodiment of the present disclosure;

FIG. 2 is a cross-sectional view illustrating a display panel of the display apparatus according to the one embodiment of the present disclosure;

FIG. 3 is a cross-sectional view of the display apparatus according to the one embodiment of the present disclosure;

FIG. 4 is a plan view of the display apparatus according to the one embodiment of the present disclosure;

FIG. 5 is a sectional view of the display apparatus according to another embodiment of the present disclosure;

FIG. 6 is a sectional view of the display apparatus according to still another embodiment of the present disclosure; and

FIG. 7 is a view illustrating an example of the display apparatus according to an embodiment of the present disclosure.

### DETAILED DESCRIPTION OF THE EMBODIMENTS

Advantages and characteristics of the present disclosure and a method of achieving them will become clear with reference to embodiments described below in detail in conjunction with the accompanying drawings. However, the present disclosure is not limited to the embodiments disclosed below and will be implemented in a variety of different forms, and the embodiments are provided to make the disclosure of the present specification complete, and to completely inform those skilled in the art of the scope of the present disclosure to which the present specification belongs, and the present disclosure is defined by the scope of the claims.

Since the shape, size, ratio, angle, and number, etc., of elements disclosed in the drawings for explaining the embodiments of the present disclosure are examples, the present disclosure is not limited to the illustrated details. Like reference numbers designate like elements throughout the disclosure. In addition, in describing the present disclosure, when it is determined that a detailed description of a related known technology can unnecessarily obscure the gist of the present disclosure, the detailed description thereof will be omitted. When “includes,” “has,” and “consists of,” etc., mentioned on the present disclosure are used, other parts can be added unless “only” is used. In a case in which a component is expressed in a singular form, a case including a plural form of the component is included unless otherwise explicitly stated.

In interpreting the components, even if there is no separate explicit description of an error range, it is interpreted as including the error range.

In the case of a description of a positional relationship, for example, when the positional relationship of two parts is described with “on top,” “upper,” “lower,” and “next to,” etc., one or more other parts can be located between the two parts unless “immediately” or “directly” is used.

In the case of a description of a temporal relationship, when a temporal precedence relationship is described with “after,” “following,” “next,” and “before,” etc., non-consecutive cases can also be included unless “immediately” or “directly” is used.

Although first, and second, etc. are used to describe various components, these components are not limited by these terms. These terms are only used to distinguish one component from another and may not define order or sequence. Accordingly, a first component mentioned below can be a second component within the technical idea of the present disclosure.

In describing the components of the present disclosure, terms such as first, second, A, B, (a), and (b) can be used. These terms are only used to distinguish one component from other components, and the nature, sequence, order, or number of the corresponding components is not limited by the terms. When an element is described as being “connected,” “coupled to,” or “joined” to another element, that element can be directly connected or coupled to the another element, but it should be understood that other components can be “interposed” between each component that is indirectly connected or connectable to each other unless specifically stated otherwise.

Further, “At least one” should be understood to include all combinations of one or more of associated elements. For example, “at least one of the first, second, and third components” means not only the first, second, or third component, but also can be said to include all combinations of two or more components of the first, second, and third components.

In the present disclosure, “a display apparatus” can include a display panel and a display device in a narrow sense, such as a liquid crystal module (LCM), an organic light emitting diode (OLED) module, a quantum dot (QD) module, which includes a drive part for driving the display panel. In addition, the display apparatus can include a laptop computer, a television, a computer monitor which are final products including an LCM, an OLED module, and a QD module, an automotive display apparatus or an electrical equipment display apparatus including parts of other forms of a vehicle, and a set electronic apparatus or a set device such as a mobile electronic apparatus including a smart phone and an electronic pad.

Accordingly, the display apparatus in the present disclosure can include a display device in a narrow sense, such as an LCM, an OLED module, and a QD module, and a set device, which is an applied product or end-consumer device including the LCM, OLED module, and QD module.

In some cases, an LCM, OLED module, and QD module, which are composed of a display panel and a driving part, can be expressed as “a display apparatus” in a narrow sense, and an electronic device as a final product including the LCM, OLED module, and QD module can be expressed as a “set device”. For example, the display apparatus in a narrow sense can include a liquid crystal display (LCD), an organic light emitting diode (OLED) or a quantum dot display panel, and a source PCB that is a control part to drive the display panel, and the set device can include a set PCB that is a set control part that is electrically connected to the source PCB and controls the entirety of the set device.

As the display panel used in the embodiments of the present disclosure, all types of display panel, such as a liquid crystal display panel, an organic light emitting diode (OLED) display panel, a quantum dot (QD) display panel, and an electroluminescent display panel, can be used. The display panel of the embodiment has a flexible substrate for an OLED display panel and a back plate support structure at a lower side and is not limited to a specific display panel in which a bezel can be bent. The display panel used in the display apparatus according to the embodiment of the present disclosure is not limited in shape and size.

For example, when the display panel is an OLED display panel, the display panel can include multiple gate lines and data lines, and pixels formed in intersections of the gate lines and/or data lines. In addition, the display panel can include an array including a thin film transistor, which is an element for selectively applying voltage to each pixel, a light emitting element layer disposed on the array, and an encapsulation substrate or an encapsulation part disposed above the array to cover the light emitting element layer. The encapsulation part can protect the thin film transistor and the light emitting element layer from an external impact and prevent moisture or oxygen from permeating into the light emitting element layer. In addition, a layer formed on the array can include an inorganic light emitting layer, for example, a nano-sized material layer or quantum dot layer.

Each feature of the various embodiments of the present disclosure can be partially or entirely coupled or combined with each other, and components thereof can be technically variously interlocked and driven. Each embodiment can be implemented independently of each other or can be implemented together in connection with each other.

Hereinafter, the embodiments of the present disclosure will be described through the accompanying drawings. Scales of components shown in the drawings have different scales from actual scales for convenience of explanation, so they are not limited to the scales shown in the drawings.

Hereinafter, various components according to the embodiments of the present disclosure will be described in detail with reference to the accompanying drawings. All the components of each display apparatus according to all embodiments of the present disclosure are operatively coupled and configured.

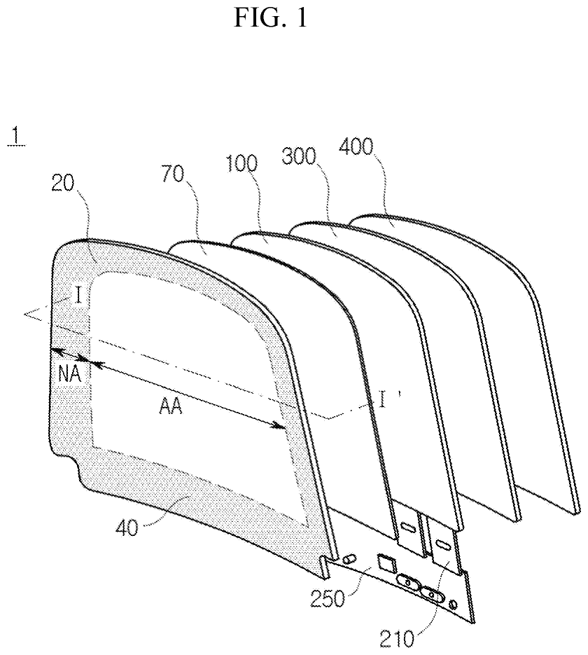

FIG. 1 is an exploded perspective view illustrating a display apparatus according to one embodiment of the present disclosure.

Referring to FIG. 1, a display apparatus 1 according to the one embodiment of the present disclosure can include a display panel 100 having an active area AA and a non-active area NA, and a support member 300 located at the lower side of the rear surface of the display panel 100. The support member 300 can support the display panel 100 at the rear surface thereof. The display apparatus 1 can include a plate 400 capable of supplementing the rigidity of the display panel 100. A size of the plate 400 on a plane can be the same as the size of the display panel 100 on a plane, but is not limited thereto.

The plate 400 can be made of any one of, for example, aluminum (Al), an aluminum alloy, silver (Ag), and a silver alloy. The embodiments of the present disclosure are not limited thereto.

Furthermore, the display apparatus 1 of the present disclosure can further include a functional film 70 and a cover member 20 at the upper side of the display panel 100 from which an image is displayed.

The cover member 20 corresponds to a display surface viewed by a viewer and is a component to which the viewer's touch can be directly applied. An area inside a dotted line illustrated in FIG. 1 is the active area AA as an area in which an actual image is projected, and an area (a surrounding area) outside the active area AA is the non-active area NA. The active area AA and the non-active area NA are respectively defined in the same corresponding areas in the display panel 100 as well. For example, the cover member 20 can be interpreted as including the active area AA and the non-active area NA. The cover member 20 is on the display surface through which a viewer views an image, and can include a cover window or cover glass through which an image is transmitted as an image transmits through a kind of transparent film or glass. Since the cover member 20 includes the active area AA displaying a screen, the cover member 20 can be made of a transparent material such as cover glass so as to display the screen. For example, the cover member 20 can be made of a transparent plastic material, a glass material, or a tempered glass material.

The cover member 20 allows light emitted from the display panel 100 to go through the cover member 20 to the outside, and is attached to protect the surface of the display panel 100. A light shielding layer 40 can be disposed on the rear surface of the non-active area NA of the cover member 20. The active area AA of the display apparatus 1 can be classified as a light transmission portion through which light generated from the display panel 100 passes, and the non-active area NA can be classified as a shielding portion through which the light does not pass. The light shielding layer 40 is disposed in the non-active area NA so that components under the non-active area NA can be prevented from being seen. The cover member 20 can be made of a material having a large Young's modulus, for example, a material of high hardness, in order to reduce cracks caused by external impact. Glass can be a representative material of high hardness, but a general glass substrate (a base material) is 0.5 mm or more in thickness, and can be broken when folded or bent. Accordingly, when the display apparatus 1 requires a flexible state, like a flexible display apparatus, or a bendable or rollable display apparatus, the cover member 20 is made of glass having a thickness of 0.1 mm or less or of a material of high hardness among transparent plastic substrates having a transmittance of a predetermined level or higher.

In this case, since an image comes out from the cover member 20, the cover member 20 can be disposed to be a top surface when viewed by a viewer. The cover member 20 is located on the uppermost side in the display apparatus 1, and can have a larger area in the non-active area NA than the functional film 70, the display panel 100, the support member 300, and the plate 400 so that relatively inner components are not visible from the outside.

In addition, the functional film 70 can include a wide-angle adjusting structure to adjust a viewing range of an image displayed on the display panel 100. The wide-angle adjusting structure can be included in the functional film 70 by having a trapezoidal pattern whose angle is adjusted to fit a desired viewing range. In most cases, the trapezoidal pattern is formed of a light blocking material. The embodiments of the present disclosure are not limited thereto. In addition, the functional film can include a polarizer that controls display characteristics (e.g., external light reflection, color accuracy, and luminance, etc.). In some cases, without being separately provided, the functional film 70 may or may not be included by being patterned on the uppermost side of the display panel 100 or the inner surface of the cover member 20. The embodiments of the present disclosure are not limited thereto.

The display panel 100 includes at least one active area AA, and pixels, which are basic units of display, are arranged in an array form in the active area. At least one non-active area NA can be disposed around or adjacent the active area AA. For example, the non-active area NA can be adjacent to at least one side surface (or part thereof) of the active area AA, or can surround completely the active area AA. The active area AA and the non-active area NA can be suitable for the design of an electronic device equipped with the display apparatus 1.

For example, the display panel 100 can be applied to a flexible display apparatus having a curve, and can be used in a form flexible in all components by encapsulating an internal array. The embodiments of the present disclosure are not limited thereto.

For example, the display apparatus 1 according to the embodiment of the present disclosure can be applied to a portion of the surface of a windshield viewed from a driver's seat or a front passenger's seat of a vehicle, or to the entirety of the windshield of the vehicle. In this case, the edge part of each component of the display apparatus 1 can be subjected to a rounding process without being straight like the edge part of the windshield of a vehicle. In addition, in the form of the display apparatus 1 after final connection thereof, the display panel 100 or other components can remain curved without being completely flat along the surface of the windshield of a vehicle. The embodiments of the present disclosure are not limited thereto.

In the display apparatus 1 according to the embodiment of the present disclosure, the rounding of the edge part and the curved state of the surface of each component can be applied not only to the display panel 100, but also to a film with a predetermined thickness, a substrate, or the cover member 20, the functional film 70, and the support member 300 which are laminated. The embodiments of the present disclosure are not limited thereto.

Each of the plurality of pixels within the active area AA can be connected to a pixel circuit. The pixel circuit can include one or more switching transistors and one or more drive transistors on the display panel 100. Each pixel circuit can be electrically connected to a gate line and a data line to communicate with at least one drive circuit, such as a gate driver and a data driver located in the non-active area. The drive circuit can be implemented as a thin film transistor (TFT) in the non-active area NA. The drive circuit can be referred to a gate-in-panel as (GIP). In addition, some components, such as a data driver integrated circuit (IC), are mounted on a printed circuit board 250 which are separated therefrom, and can be combined with a connection interface (a pad/bump, and a pin, etc.) disposed in the non-active area NA by using a signal transmission film 210 such as a flexible printed circuit board (FPCB), a chip-on-film (COF), and a tape-carrier-package (TCP), etc.

The display panel 100 can include various additional elements for generating various signals or driving pixels within the active area. The additional elements can include an inverter circuit, a multiplexer, and an electrostatic discharge circuit, etc. With the connection interface disposed in the non-active area of the display panel 100, the lower end part or upper end part of the non-active area NA of the display panel 100 can be formed to protrude more. Together with the signal transmission film 210, the printed circuit board 250 is folded to the side of the rear surface of the plate 400, and thus can prevented from being seen from the cover member 20.

A functional member can be provided on the lower side of the functional film 70 and on the upper side of the display panel 100. The functional member can be provided to reinforce mechanical and optical characteristics needed for the display panel 100. The functional member can also include additional elements related to functions other than pixel driving. For example, the functional member can include additional elements providing a touch sensing function, a user authentication function (e.g., fingerprint recognition), a multi-level pressure sensing function, and a tactile feedback function, etc. The functional member can be attached to the upper surface of the display panel 100 by adhesive.

The plate 400 serves as a housing constituting the rear surface of an outermost part of the display apparatus 1, and can be formed of various materials such as plastic, metal, aluminum, or glass.

In this case, the plate 400 can function as a casing constituting the outermost part of the display apparatus 1, but the embodiments of the present disclosure are not limited thereto.

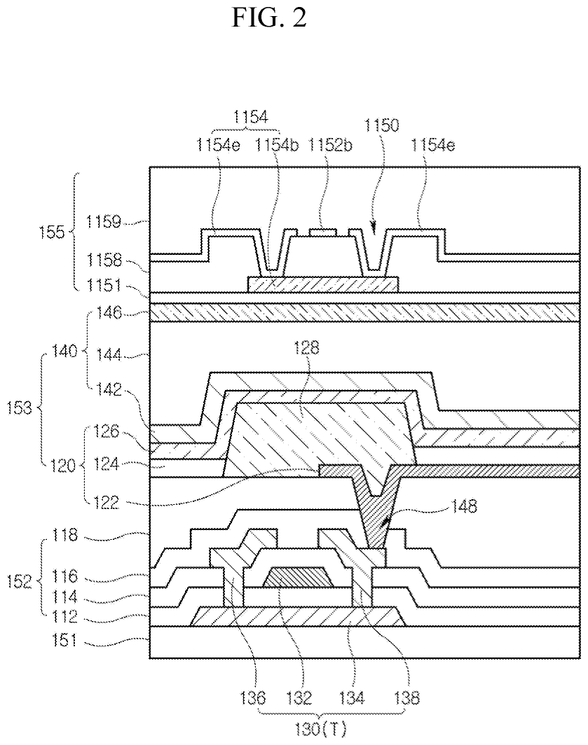

FIG. 2 is a cross-sectional view illustrating the display panel of the display apparatus according to the embodiment of the present disclosure.

Particularly, FIG. 2 is the cross-sectional view illustrating the display panel in the active area AA according to the embodiment of the display apparatus 1 of the present disclosure. FIG. 2 illustrates a light emitting element as an example, but the embodiments of the present disclosure are not limited thereto.

As illustrated in FIG. 2, in the display panel 100, a thin film transistor array 152 and a light emitting element array 153 are stacked on the substrate 151, and a touch part 155 is positioned on the light emitting element array 153. Additional elements providing a user authentication function (e.g., fingerprint recognition), a multi-level pressure sensing function, and a tactile feedback function, etc. can be provided on the light emitting element array 153 in addition to a position on the touch part 155.

The thin film transistor array 152 and the light emitting element array 153 respectively include at least one thin film transistor (TFT) and the light emitting element 120 connected to the thin film transistor for each of a plurality of sub-pixels defined in matrix in the active area AA of the substrate 151. This will be described in detail with reference to FIG. 2.

The substrate 151 supports various components of the display panel 100. The substrate 151 can serve as a base substrate for the display panel 100.

For example, the substrate 151 can include polyimide, which is a plastic material having flexibility, or can be made of a thin glass material having flexibility.

The substrate 151 can be formed of a transparent insulating material, such as glass or plastic. When the substrate 151 is made of plastic, the substrate 151 can be a flexible plastic film, a plastic substrate, or a flexible substrate. For example, the substrate 151 can be in the form of a film including one of polyimide-based polymers, polyester-based polymers, silicone-based polymers, acrylic polymers, polyolefin-based polymers, and copolymers thereof, but the embodiments of the present disclosure are not limited thereto. Among these materials, polyimide is used as a plastic substrate because polyimide can be applied to high-temperature processing and can be coated. The substrate (an array substrate) can include elements and functional layers formed on the substrate 151, for example, a switching TFT, a driving TFT connected to the switching TFT, a light emitting element connected to the driving TFT, and a protective film, but the embodiments of the present disclosure are not limited thereto.

In some cases, a buffer layer can be placed on the substrate 151. The buffer layer is a functional layer for protecting the thin film transistor (TFT) from impurities such as alkali ions flowing out from the substrate 151 or lower layers. The buffer layer can be made of silicon oxide (SiOx), silicon nitride (SiNx), or multiple layers thereof, and the embodiments of the present disclosure are not limited thereto.

The thin film transistor array 152 can include the thin film transistor (TFT) 130 in which a gate electrode 132, a gate insulating film 112, a semiconductor layer 134, an interlayer insulating film 114, the source and drain electrodes 136, 138 are sequentially disposed. At least one thin film transistor (TFT) 130 can be included in a plurality of sub-pixels provided in the active area AA on the substrate 151.

The arrangement order of the semiconductor layer 134 and the gate electrode 132 can be changed.

The semiconductor layer 134 is located at a predetermined portion on the substrate 151 or the buffer layer. The semiconductor layer 134 can be made of polysilicon (p-Si), and in this case, a predetermined area can be doped with impurities. In addition, the semiconductor layer 134 can be made of amorphous silicon (a-Si) or various organic semiconductor materials such as pentacene. Furthermore, the semiconductor layer 134 can be made of oxide. The gate insulating film 112 can be formed of an insulating inorganic material such as silicon oxide (SiOx) or silicon nitride (SiNx), or can be formed of an insulating organic material. The gate electrode 132 can be made of various conductive materials, such as magnesium (Mg), aluminum (Al), nickel (Ni), chromium (Cr), molybdenum (Mo), tungsten (W), gold (Au), or alloys thereof, and the embodiments of the present disclosure are not limited thereto.

The interlayer insulating film 114 can be formed of an insulating inorganic material such as silicon oxide (SiOx) or silicon nitride (SiNx), and can also be formed of an insulating organic material. By selectively removing the interlayer insulating film 114, a contact hole through which source and drain areas are exposed can be formed.

The source and drain electrodes 136 and 138 are formed on the interlayer insulating film 114 in a single-layer or multi-layer shape as an electrode material.

An inorganic protective film 116 and a first planarization layer 118 can cover the source and drain electrodes 136, 138, and can be located on the thin film transistor. The inorganic protective film 116 and the first planarization layer 118 protect the thin film transistor and planarize a top thereof. The inorganic protective film 116 can be formed of an inorganic insulating film such as a silicon nitride (SiNx) film or a silicon oxide (SiOx) film, and the embodiments of the present disclosure are not limited thereto. The first planarization layer 118 can be made of an organic insulating layer such as Benzocyclobutene (BCB) or acrylic, and the embodiments of the present disclosure are not limited thereto. The inorganic protective film 116 and the first planarization layer 118 can each be formed as a single layer or configured as double or multiple layers, and in some cases, any one of the two layers can be omitted.

The thin film transistor array 152 can include the thin film transistor (TFT) 130 provided in each sub-pixel on the substrate 151, the inorganic protective film 116, and the first planarization layer 118.

The light emitting element 120 contacting the thin film transistor (TFT) can have a form in which a first electrode 122, a light emitting layer 124, and a second electrode 126 are sequentially disposed. For example, the light emitting element 120 can include the first electrode 122 in contact with the drain electrode 138 through a contact hole 148 formed in the first planarization layer 118 and the inorganic protective film 116, the light emitting layer 124 located on the first electrode 122, and the second electrode 126 located on the light emitting layer 124.

When the display panel 100 is a top emission type in which light is emitted to the top of the second electrode 126, the first electrode 122 can include an opaque conductive material having high reflectivity. For example, the reflective conductive material can be silver (Ag), aluminum (Al), gold (Au), molybdenum (Mo), tungsten (W), chromium (Cr), or an alloy thereof, and the embodiments of the present disclosure are not limited thereto.

A bank 128 opens a light emitting area and can be formed in the remaining area except for the light emitting area. Accordingly, the bank 128 can have a bank hole corresponding to the light emitting area and exposing the first electrode 122. The bank 128 can be made of an inorganic insulating material such as silicon nitride (SiNx) or silicon oxide (SiOx), or an organic insulating material such as BCB, acrylic resin or imide resin, and the embodiments of the present disclosure are not limited thereto.

The light emitting layer 124 is located on the first electrode 122 exposed to the bank 128. The light emitting layer 124 can include a hole injection layer, a hole transport layer, a light emitting layer, an electron transport layer, and an electron injection layer, but the embodiments of the present disclosure are not limited thereto.

In addition, the light emitting layer 124 can be configured as a single light emitting layer structure which emits a ray of light in a single stack, or as a multiple stack structure including multiple stacks with each of the stacks including a single light emitting layer of the same color. In this case, for displaying various colors, adjacent sub-pixels can be arranged to emit different luminous colors. For example, sub-pixels having red, green, and blue light emitting layers can be arranged side by side or in a triangular shape. In some cases, an arrangement of white sub-pixels can be added. In addition, with the arrangement structure of the light emitting layer 124, white color can be expressed by stacking a plurality of stacks including light emitting layers emitting different colors. When white color is expressed in a stacked structure, a separate color filter can be further added to each sub-pixel. But the embodiments of the present disclosure is not limited thereto.

The second electrode 126 is located on the light emitting layer 124. When the display panel 100 is a top emission type, the second electrode 126 is formed of a transparent conductive material such as indium tin oxide (ITO) or indium zinc oxide (IZO), or formed of a semi-permeable metal or metal alloy such as Mg—Ag alloy, so light generated in the light emitting layer 124 can be emitted to the top of the second electrode 126.

In FIG. 2, the light emitting element array 153 can include the light emitting element 120 having the first electrode 122, the light emitting layer 124, and the second electrode 126 stacked on the thin film transistor array 152, and a capping layer provided on the second electrode 126. The capping layer protects the light emitting element 120 and helps extract light from the second electrode 126.

The light emitting element array 153 includes the encapsulation part 140. The encapsulation part 140 prevents the penetration of oxygen and moisture from the outside in order to prevent oxidation of a light emitting material and an electrode material. When the light emitting element 120 is exposed to moisture or oxygen, a pixel shrinkage phenomenon in which a light emitting area is reduced can occur or a dark spot can occur in the light emitting area. The encapsulation part 140 includes first and second inorganic films 142, 146 made of glass, metal, aluminum oxide (AlOx) or a silicon (Si)-based material, and an organic film 144 acting as a buffer layer to relieve a stress between each layer due to the bending of the display panel 100 and enhancing a planarization performance in such a manner that the first inorganic film 142, the organic film 144, and the second inorganic film 146 are alternately formed.

Here, the component of the organic film 144 can be an organic insulating material such as acrylic resin, epoxy resin, polyimide, polyethylene or silicon oxycarbon (SiOC), but the embodiments of the present disclosure are not limited thereto. In this case, the first and second inorganic films 142 and 146 can function to block the penetration of moisture or oxygen, and the organic film 144 can function to level the surface of the first inorganic film 142. A reason in which the encapsulation part is formed with multiple thin film layers can be to make the movement path of moisture or oxygen longer and more complicated compared to an encapsulation part formed with a single layer, and to block the penetration of moisture/oxygen to the light emitting element array 153.

For another example, in some cases, a protective layer can be formed between the light emitting element 120 and the encapsulation part 140 and can perform a function of protecting the encapsulation part 140 so that the side surface of the encapsulation part 140 is not peeled off or the uniformity of the encapsulation part 140 is not affected during the manufacturing process of the encapsulation part 140. In some cases, since the encapsulation part 140 is a component essential to the light emitting element 120, which is vulnerable to moisture, the encapsulation part 140 can be regarded as a component of the light emitting element array 153. FIG. 2 illustrates the light emitting element array 153 including the encapsulation part 140 and the light emitting element 120.

The display panel 100 of the present disclosure further includes the touch part 155 provided on the light emitting element array 153 to recognize a viewer's (a user's) touch.

A touch buffer layer 1151 can be disposed on the encapsulation part 140. The touch buffer layer 1151 can be disposed on the front surface of the active area AA and the non-active area NA, and can be disposed by extending to a pad part. The touch buffer layer 1151 can be an insulating layer, and a term thereof is not limited.

The touch buffer layer 1151 can be formed of at least one inorganic material of silicon nitride (SiNx), silicon oxide (SiOx), and aluminum oxide (AlyOz), but is not limited thereto.

A first touch electrode 1154 can be disposed on the touch buffer layer 1151.

The touch part 155 includes the first touch electrode 1154 and a second touch electrode (the same layer as 1152b) which are arranged to cross each other, and one of the touch electrodes receives a voltage signal and the other one thereof senses a voltage signal. Each of the first touch electrode 1154 and the second touch electrode are provided with main patterns 1154e patterned in the same polygonal or circular shapes on a touch insulation film 1158 such that the main patterns 1154e are spaced apart from each other, and to connect adjacent main patterns to each other, first and second bridge patterns 1154b and 1152b are shown on different layers. In the drawing, the first bridge pattern 1154b is configured directly on the upper side of the light emitting element array 153, but is not limited thereto.

An insulating film or an insulating substrate can be provided on the light emitting element array 153, and the first bridge pattern 1154b can be provided thereon. The second bridge pattern 1152b is located on the same layer as the main patterns of the second touch electrode, for example, on the touch insulation film 1158, and can be formed integrally with the touch insulation film 1158. In this case, the main patterns 1154e of the first touch electrode 1154 are spaced apart from the second touch electrode to be electrically separated therefrom; however, the embodiments of the present disclosure are not limited thereto.

In the touch part 155, a first flexible film can contact touch pads positioned at one ends of the first touch electrode 1154 and the second touch electrode (the same layer as 1152b) for voltage signal application and signal sensing. For example, the touch pads can be located on the same layer as the first bridge pattern 1154b, for example, on the upper side of the light emitting element array 153. But the embodiments of the present disclosure are not limited thereto.

A second planarization layer 1159 can be disposed on the second touch electrode (the same layer as 1152b) and the first bridge pattern 1154b.

The second planarization layer 1159 can cover and planarize the second touch electrode (the same layer as 1152b), the first bridge pattern 1154b, and the touch insulation film 1158. In addition, the second planarization layer 1159 can be made of at least one organic insulating material such as BenzoCycloButene (BCB), acrylic resin, epoxy resin, phenolic resin, polyamide resin, or polyimide resin, but is not limited thereto.

An adhesive layer and the cover member 20 can be disposed on the second planarization layer 1159.

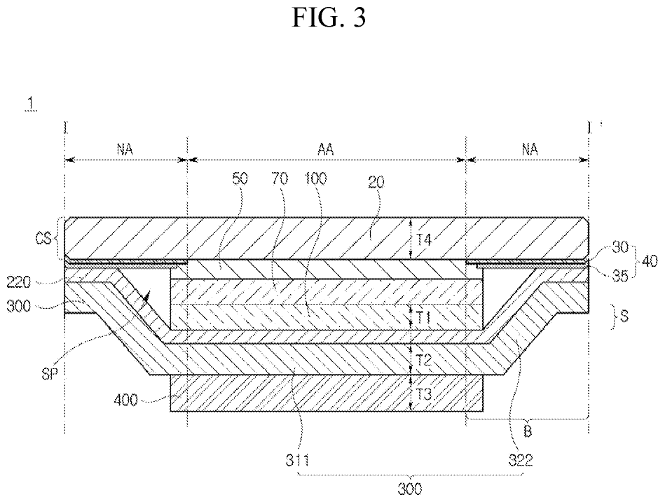

FIG. 3 is a cross-sectional view of the display apparatus according to the one embodiment of the present disclosure. More specifically, FIG. 3 is the cross-sectional view taken along line I-I′ of FIG. 1.

Referring to FIGS. 1 and 3, the display apparatus 1 can include the display panel 100 and various layers such as the functional film 70, the support member 300, and the plate 400.

The cover member 20 can be disposed by including the active area AA and the non-active area NA.

A first fixing layer 50 fixing the display panel 100 to the cover member 20 can be disposed on the rear surface of the cover member 20. The first fixing layer 50 completely overlaps the active area AA and can also be disposed in a portion of the non-active area NA. A rear printed part B can be disposed on the rear surface of the cover member 20. The rear printed part B can overlap with the non-active area NA. The light shielding layer 40 can be disposed on the rear printed part B. The cover member 20 can include the light shielding layer 40 on the rear surface thereof so that the light shielding layer 40 covers an outer part of the rear surface on which an image is displayed. The light shielding layer 40 is disposed overlapping with the non-active area NA to prevent components under the non-active area NA from being seen.

The light shielding layer 40 can be an opaque masking layer such as black ink (e.g., a polymer filled with carbon black).

The light shielding layer 40 according to the embodiment of the present disclosure can be formed as a multilayer structure composed of a first light shielding layer 30 and a second light shielding layer 35, but can be composed of more than two layers.

The first light shielding layer 30 and the second light shielding layer 35 can be formed of a material having low light transmittance. The first light shielding layer 30 and the second light shielding layer 35 can be combined with each other to implement a black color.

The first light shielding layer 30 and the second light shielding layer 35 of the light shielding layer 40 are intended to block light and define the edge of the active area AA, and the light shielding layer 40 does not have to have the two layers. As long as a black color can be implemented with one layer, the light shielding layer 40 can have one layer.

Since the first fixing layer 50 can be disposed to overlap the active area AA, the first fixing layer 50 can be formed of a transparent adhesive member. For example, the first fixing layer 50 can be formed of a material such as optical clear adhesive (OCA), optical clear resin (OCR), or pressure sensitive adhesive (PSA), or can include the same, but the embodiments of the present disclosure are not limited thereto.

The functional film 70 can be disposed between the first fixing layer 50 the display panel 100. The functional film 70 can have a stacked form of one or more functional layers, but the embodiments of the present disclosure are not limited thereto.

For example, the functional film 70 can include a polarizer or an antireflection layer capable of improving outdoor visibility and contrast ratio of an image displayed on the display panel 100 by preventing reflection of external light.

In addition, the functional film 70, for example, can further include a barrier layer to prevent penetration of moisture or oxygen to the functional film. The barrier layer can be made of a material such as a polymer material having low moisture permeability.

The functional film 70 completely overlaps the active area AA, and can be disposed even in a portion of the non-active area NA.

The display panel 100 completely overlaps the active area AA, and can be disposed in a portion of the non-active area NA. The display panel 100 can include a side surface S.

At least one support member 300 can be provided under the substrate 151 of the display panel 100, for example, on a side opposite to the display surface, in order to increase strength and rigidity of the display panel 100. The support member 300 can be attached to a surface (a second surface) opposite to a surface (a first surface) having the light emitting element among the opposite surfaces of the substrate 151. Since the substrate 151 included in the display panel 100 can be made of a plastic material having flexibility, the substrate 151 is a flexible substrate. In this case, in a situation in which a panel manufacturing substrate made of glass as an example is disposed under the substrate, the manufacturing process of the display apparatus 1 is performed, and after members such as a polarizer are disposed on the display panel 100, the panel manufacturing substrate can be released.

The support member 300 can be disposed under a substrate provided in the display panel 100. After the panel manufacturing substrate is released, members for supporting the substrate of the display panel 100 are needed, and thus the support member 300 for supporting the substrate 151 can be disposed under the substrate. The support member 300 can protect the display panel 100 from external moisture, heat, and impact.

A size of the support member 300 on a plane can be greater than a size of the display panel 100 on a plane. For example, the support member 300 can extend from and beyond the opposite side surfaces S of the display panel 100 so that the entire display panel 100 is covered by the support member 300. In this case, a second fixing layer 220 can be disposed between the display panel 100 and the support member 300. In this case, the area of the second fixing layer 220 can be equal to the area of the support member 300. However, the embodiments of the present disclosure are not limited thereto, and the area of the second fixing layer 220 can be smaller or larger than the area of the display panel 100 in size.

The plate 400 can be disposed on the lower side of the support member 300. The plate 400 can be formed of a rigid material capable of providing rigidity to the foldable display apparatus 1 having a flexible characteristic. Accordingly, the plate 400 can protect the support member 300 and the display panel 100. The support member 300 can be made of polyethylene naphthalate (PEN), polyethylene terephthalate (PET), polyethylene ether phthalate, polycarbonate, polyarylate, polyether imide, polyether sulfonate, polyimide, polyacrylate, or a thin film configured as a combination of other suitable polymers, but the embodiments of the present disclosure are not limited thereto. Other suitable materials that can be used in the formation of the support member 300 can be thin glass, metal foil shielded with a dielectric, a multilayer polymer, and a polymer film including nanoparticles or polymeric materials combined with microparticles, but the embodiments of the present disclosure are not limited thereto. The support member 300 can be thicker than the substrate of the display panel 100 (see 151 of FIG. 2) for supporting the display panel.

Hereinafter, the support member 300 according to the embodiment of the present disclosure which can prevent the permeating of moisture to the display apparatus 1 and the scratching of the rear surface of the cover member 20 will be described in detail with reference to FIGS. 3, 4, 5, and 6.

Referring to FIG. 3, the support member 300 according to the embodiment of the present disclosure can include a base part 311, and at least one extension part 322 extending from the base part 311 along at least one edge part of the base part 311. For example, the extension part 322 of the support member 300 can protrude more outward than one side surface of the base part 311 of the support member 300. The extension part 322 can be directly connected to the base part 311.

For example, the base part 311 of the support member 300 can be an area which completely overlaps the display panel 100, and the extension part 322 can be an area extending outward from the side surface S of the display panel 100. For example, the base part 311 can overlap the entirety of the active area AA, and a portion of the non-active area NA, and the extension part 322 can overlap the non-active area NA. The extension part 322 can cover the side surfaces S of the display panel 100 from the outside.

The extension part 322 of the support member 300 to which the second fixing layer 220 is attached can overlap the cover member 20 through the second fixing layer 220.

The area of the second fixing layer 220 to which the support member 300 is attached can be equal to or greater than the area of the first fixing layer 50 to which the functional film 70 or the display panel 100 is attached.

The support member 300 including the extension part 322 can have a larger area than the display panel 100. In addition, the support member 300 can cover the side surface of the display panel 100 with the extension part 322 extending from the base part 311 parallel to the display panel 100, and can include a curved surface.

For example, as illustrated in FIG. 3, the extension part 322 includes a first part extending along the extension direction of the base part 311, a second part attached to the light shielding layer 40 through the second fixing layer 220, and a third part between the first part and the second part. The second part extends along the extension direction of the base part 311, and the third part can be a curved surface that is curved compared to the first part and the second part. The extension part 322 of the support member 300 can be attached to the rear printed part B of the light shielding layer 40 of the cover member 20 through the second fixing layer 220. The rear printed part B can be an area in which the light shielding layer 40 and the first fixing layer 50 do not overlap. The extension part 322 can bend in a direction toward the rear printed part B of the cover member 20 in the non-active area NA relative to the base part 311 in the active area AA.

When the support member 300 has the same area as the display panel 100, for example, when the extension part 322 is not provided, for example, when only the base part 311 of the support member 300 is provided, the side surface S of the display panel 100 including an organic light emitting element can be exposed to the outside and vulnerable to moisture permeation from the outside. In addition, the rear printed part B of the cover member 20 in which the light shielding layer 40 is disposed is exposed to the outside, so the rear printed part B can be scratched during a module manufacturing process or by handling during shipping. However, when the support member 300 includes the extension part 322, the permeation of external moisture to the side surface of the display panel 100 can be prevented, and accordingly, defects such as dark spots, black spots, and discoloration of the polarizer can be improved.

In addition, since the extension part 322 can protect the rear printed part B of the cover member 20, a separate protective film is not required or needed to be attached thereto, and accordingly, materials can be saved and process time can be reduced. In addition, the display panel 100 can be prevented from being damaged by external force.

Since the support member 300 is required or needed to support the display panel 100, the thickness T2 of the support member 300 can be larger than the thickness T1 of the display panel 100 (T2>T1). Since the plate 400 complements the rigidity of the display panel 100 and the support member 300, the thickness T3 of the plate 400 can be larger than the thickness T2 of the support member 300 (T3>T2).

The cover member 20 is required or needed to cover and protect the surface of the display panel 100 by being located on the front surface of the display apparatus 1, and thus the thickness T4 of the cover member 20 can be larger than the thickness T2 of the support member 300 and the thickness T3 of the plate 400 (T4>T2, T4>T3).

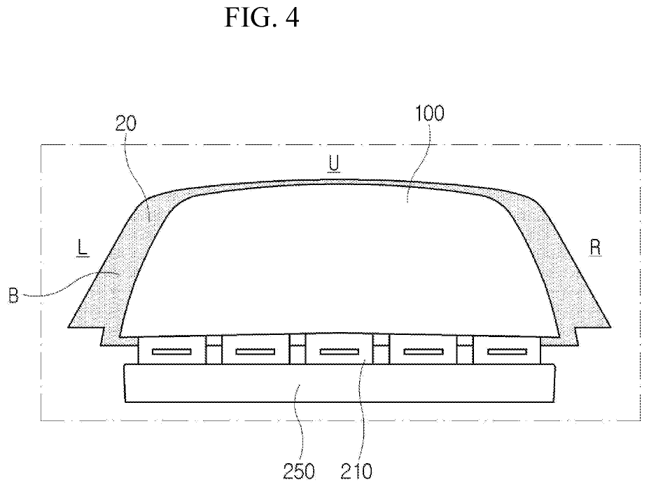

FIG. 4 is a plan view of the display apparatus according to the embodiment of the present disclosure. Particularly, FIG. 4 is the plan view illustrated from the lower surface of the display panel.

Referring to FIG. 4, the cover member 20, which is located at the outermost part and can be touched directly by a user, is required or needed to cover all lower components, so the cover member 20 can include more area of the non-active area NA more than other components (for example, the display panel, the support member, and the plate).

The display apparatus 1 can include the signal transmission film 210 and the printed circuit board 250 at the lower side of the display apparatus. Accordingly, the extension part 322 of the support member 300 of FIG. 3 can extend to the left side L, right side R, and upper side U relative to the base part 311 of the support member 300 in the display apparatus 1 of FIG. 4. Accordingly, the extension part 322 can cover the rear printed part B of the cover member 20.

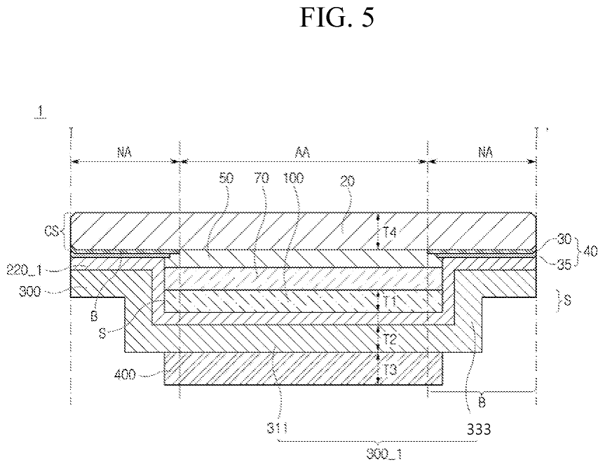

FIG. 5 is a sectional view of the display apparatus according to another embodiment of the present disclosure. Particularly, FIG. 5 is a sectional view taken along line I-I′ of FIG. 1 and illustrates the changed position of the extension part 322 of the support member 300 illustrated in FIG. 3. Accordingly, in the following description, descriptions of components other than the extension part 322 of the support member 300 and components related thereto will be omitted or simplified.

Referring to FIG. 5, the support member 300_1 according to the another embodiment of the present disclosure can include a base part 311, and at least one extension part 333 attached to the base part 311 along at least one edge part of the base part 311.

For example, the base part 311 of the support member 300_1 can be an area completely overlapping the display panel 100, and the extension part 333 can be an area extending outward from the side surface S of the display panel 100. For example, the extension part 333 can be disposed in the outermost area of the active area AA and the non-active area NA. The extension part 333 can contact the side surface S of the display panel 100. The base part 311 and the extension part 333 of the support member 300_1 can be integrated with each other.

The extension part 333 of the support member 300_1 to which a second fixing layer 220_1 is attached can overlap the cover member 20 through the second fixing layer 220_1.

The extension part 333 of the support member 300_1 can be attached to the light shielding layer 40 on the rear surface of the cover member 20 through the second fixing layer 220_1.

The extension part 333 of the support member 300_1 to which the second fixing layer 220_1 is attached can be completely attached to the side surface S of the display panel 100. Accordingly, the effect of preventing the permeation of moisture to the display panel 100 including the organic light emitting element can be maximized.

The process method of bringing the extension part 333 into close contact with the side surface S of the display panel 100 without creating an air gap (SP in FIG. 3) between the side surface S of the display panel 100 and the extension part 333 of the support member 300_1 will be described as follows.

First, the display panel 100 can be attached to the functional film 70 and the cover member 20.

Second, the support member 300_1 having the extension part 333 to which the second fixing layer 220_1 is attached can be prepared.

Third, through a thermoforming and vacuum bonding process of the rear surface of the support member 300_1 by using a hot plate in a vacuum chamber, the support member 300_1 can be attached to the lower and side surfaces of the display panel 100 and the rear surface of the cover member 20.

The process method is intended to explain the embodiments of the present disclosure, but the embodiments of the present disclosure are not limited thereto.

The second fixing layer 220_1 located on the rear surface of the display panel 100 and attached to the support member 300 can contact the cover member 20.

The area of the second fixing layer 220_1 to which the support member 300 is attached can be equal to or greater than the area of the first fixing layer 50 to which the functional film 70 or the display panel 100 is attached.

The extension part 333 is a part formed by extending the base part 311, which is located under the display panel 100, more outward than the display panel 100. Accordingly, the area of the support member 300_1 including the extension part 333 can be larger than the area of the display panel 100. When the support member 300_1 has the same area as the area of the display panel 100, for example, when the extension part 333 is not provided, for example, when only the base part 311 of the support member 300_1 is provided, the side surface of the display panel 100 including the organic light emitting element is exposed to the outside and vulnerable to moisture permeation from the outside. In addition, the rear printed part B of the cover member 20 is exposed to the outside, and can be scratched during a module manufacturing process or by handling during shipping.

However, when the support member 300_1 includes the extension part 333, the permeation of external moisture to the side surface S of the display panel 100 can be prevented, and accordingly, defects such as dark spots, black spots, and discoloration of the polarizer can be improved. In addition, since the extension part 333 can protect the rear printed part B of the cover member 20, a separate protective film is not required or needed to be attached thereto, and accordingly, materials can be saved and process time can be reduced. In addition, the display panel 100 can be prevented from being damaged by external force.

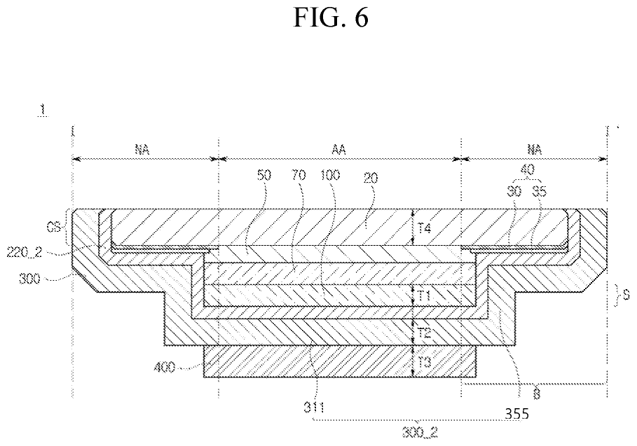

FIG. 6 is a sectional view of the display apparatus according to still another embodiment of the present disclosure.

Referring to FIG. 6, the support member 300_2 according to the still another embodiment can include a base part 311, and at least one extension part 355 extending from the base part 311 along at least one edge part of the base part 311. For example, the extension part 355 of the support member 300 can protrude more outward than one side surface of the base part 311 of the support member 300_2.

For example, the base part 311 of the support member 300_2 can be an area which completely overlaps the display panel 100, and the extension part 355 can be an area extending outward from the side surface S of the display panel 100. For example, the extension part 355 can be disposed in the outermost area of the active area AA and the non-active area NA.

The extension part 355 of the support member 300 on which a second fixing layer 220_2 is attached can overlap the cover member 20 through the second fixing layer 220_2.

The extension part 355 of the support member 300_2 can extend to the side surface CS of the cover member 20. Since the extension part 355 of the support member 300_2 covers the side surface CS of the cover member 20 with the second fixing layer 220_2, the effect of preventing the cracking of the side surface CS of the cover member 20 can be added. The second fixing layer 220_2 can block moisture that can be introduced to the cover member 20, so the prevention of the permeating of moisture to the cover member 20 and the protection of the cover member 20 from external forces can be maximized.

The area of the second fixing layer 220_2 to which the support member 300_2 is attached can be equal to or greater than the area of the first fixing layer 50 to which the functional film 70 or the display panel 100 is attached.

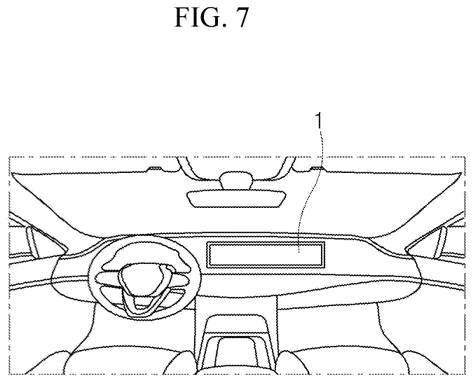

FIG. 7 is a view illustrating an example of the display apparatus according to the embodiment of the present disclosure. In this example, FIG. 7 is a view illustrating the inside of a vehicle equipped with the display apparatus.

Referring to FIG. 7, the display apparatus 1 can be disposed on at least a portion of the dashboard of a vehicle. The dashboard of a vehicle includes components disposed on front surface of the front seat of the vehicle (e.g., a driver's seat, and a front passenger's seat). For example, input components for manipulating various functions (e.g., an air conditioner, an audio system, and a navigation system) inside the vehicle can be disposed on the dashboard of a vehicle.

In the embodiment, the display apparatus 1 can be disposed on a dashboard of a vehicle and operate as an input unit for manipulating at least some of various functions of the vehicle. The display apparatus 1 can provide various information related to a vehicle, such as the driving information of a vehicle (e.g., the current speed, remaining fuel amount, mileage of a vehicle), and information on parts of a vehicle (e.g., the degree of damage to a tire of a vehicle).

In the embodiment, the display apparatus 1 can be disposed to span a driver's seat and a passenger's seat disposed in a front side inside a vehicle. Users of the display apparatus 1 can include a driver of a vehicle and a passenger in the front passenger seat. Both the driver and passenger of a vehicle can use the display apparatus 1.

In the embodiment, the display apparatus 1 illustrated in FIG. 7 can show a part thereof. The display apparatus 1 illustrated in FIG. 7 can show the display panel of various components included in the display apparatus 1. Among components of the display apparatus 1, components other than the part illustrated in FIG. 7 can be mounted inside a vehicle (or at least a portion thereof). FIG. 7 illustrates an embodiment of the present disclosure, and the present disclosure is not limited thereto. For example, the display apparatus of the present disclosure can be used or implemented in any other device or system such as a wearable device, a mobile terminal, a navigation device, a gaming device, etc.

A display apparatus according to one or more embodiments of the present disclosure includes a support member, a display panel located above the support member, a fixing layer between the support member and the display panel, a cover member located above the display panel and including an active area and a non-active area around the active area, and at least one light shielding layer disposed on the rear surface of the cover member and overlapping the non-active area. The support member includes a base part overlapping the display panel and at least one extension part extending from the base part and protruding from a side surface of the display panel, wherein the extension part can cover the side surface of the display panel.

According to the embodiments of the present disclosure, the support member can include polyethylene terephthalate (PET).

According to the embodiments of the present disclosure, the extension part of the support member can be attached to the at least one light shielding layer disposed on the rear surface of the cover member through the fixing layer.

According to the embodiments of the present disclosure, the extension part can bend in a direction toward the at least one light shielding layer of the cover member in the non-active area relative to the base part.

According to the embodiments of the present disclosure, the extension part can include a curved surface.

According to the embodiments of the present disclosure, the extension part can be in contact with the side surface of the display panel.

According to the embodiments of the present disclosure, the base part and the extension part can be integrated with each other.

A display apparatus according to one or more embodiments of the present disclosure includes a display panel having an active area and a non-active area, a cover member disposed above the display panel, a support member disposed under the display panel, and a fixing layer configured to attach the support member. The area of the support member can be larger than the area of the display panel.

According to the embodiments of the present disclosure, the cover member includes at least one rear printed part, and the extension part of the support member can be attached to at least one rear printed part of the cover member through the fixing layer.

According to the embodiments of the present disclosure, the support member can cover the side surface of the display panel.

According to the embodiments of the present disclosure, the support member can extend to the side surface of the cover member.

According to the embodiments of the present disclosure, the display apparatus can further include a plate on a lower side of the support member, wherein the plate can include aluminum.

According to the embodiments of the present disclosure, the display panel can include an organic light emitting element, an encapsulation part, and a touch part.

According to the embodiments of the present disclosure, the display panel can include a printed circuit board on a lower side thereof, and the support member on a plane can extend to upper, left, and right sides of the display panel except for a direction toward the printed circuit board on the lower side of the display panel.

According to the embodiments of the present disclosure, the thickness of the support member can be larger than the thickness of the display panel, and the thickness of the cover member can be larger than the thickness of the support member.

Although the embodiments of the present disclosure have been described in more detail with reference to the accompanying drawings, the present disclosure is not necessarily limited to these embodiments, and various modifications thereof can be made within the scope of the technical idea of the present disclosure. Accordingly, the embodiments disclosed in the present disclosure are not intended to limit the technical idea of the present disclosure, but to explain the same, and the scope of the technical idea of the present disclosure is not limited by these embodiments. Therefore, it should be understood that the embodiments described above are illustrative in all respects and not restrictive. The scope of protection of the present disclosure should be interpreted according to the scope of the claims, and all technical ideas within the scope equivalent to the scope of the claims should be interpreted as being included in the scope of the claims of the present disclosure.

What is claimed is:

1. A display apparatus comprising:
a support member;
a display panel located above the support member;
a fixing layer between the support member and the display panel;
a cover member located above the display panel and comprising an active area and a non-active area adjacent the active area; and
at least one light shielding layer disposed on a rear surface of the cover member and overlapping the non-active area,
wherein the support member comprises a base part overlapping the display panel and at least one extension part extending from the base part and protruding from a side surface of the display panel, and
wherein the at least one extension part of the support member covers the side surface of the display panel.

2. The display apparatus of claim 1, wherein the support member comprises polyethylene terephthalate (PET).

3. The display apparatus of claim 1, wherein the at least one extension part of the support member is attached to the at least one light shielding layer disposed on the rear surface of the cover member through the fixing layer.

4. The display apparatus of claim 1, wherein the at least one extension part of the support member bends in a direction toward the at least one light shielding layer in the non-active area relative to the base part.

5. The display apparatus of claim 1, wherein the at least one extension part of the support member comprises a curved surface.

6. The display apparatus of claim 1, wherein the at least one extension part of the support member is in contact with the side surface of the display panel.

7. The display apparatus of claim 1, wherein the base part and the at least one extension part of the support member are integrated with each other.

8. The display apparatus of claim 1, wherein the display panel comprises a printed circuit board on a lower side of the display panel, and
the support member on a plane extends to upper, left, and right sides of the display panel except for a direction toward the printed circuit board on the lower side of the display panel.

9. The display apparatus of claim 1, wherein a thickness of the support member is larger than a thickness of the display panel, and a thickness of the cover member is larger than the thickness of the support member.

10. A display apparatus comprising:
a display panel having an active area and a non-active area;
a cover member disposed on the display panel;
a support member disposed under the display panel; and
a fixing layer configured to attach the support member to the cover member,
wherein an area of the support member is larger in size than an area of the display panel.

11. The display apparatus of claim 10, wherein the support member comprises polyethylene terephthalate (PET).

12. The display apparatus of claim 10, wherein the cover member comprises at least one rear printed part, and
the support member is attached to the at least one rear printed part of the cover member through the fixing layer.

13. The display apparatus of claim 10, wherein the support member covers a side surface of the display panel.

14. The display apparatus of claim 10, wherein the support member extends to a side surface of the cover member.

15. The display apparatus of claim 10, further comprising:
a plate disposed on a lower side of the support member,
wherein the plate comprises aluminum.

16. The display apparatus of claim 10, wherein the display panel comprises an organic light emitting element, an encapsulation part, and a touch part.

17. The display apparatus of claim 10, wherein the display panel comprises a printed circuit board on a lower side of the display panel, and
the support member on a plane extends to upper, left, and right sides of the display panel except for a direction toward the printed circuit board on the lower side of the display panel.

18. The display apparatus of claim 10, wherein a thickness of the support member is larger than a thickness of the display panel, and a thickness of the cover member is larger than the thickness of the support member.
